(19) United States
(12) Patent Application Publication
(10) Pub. No.: US 2026/0029296 A1
(43) Pub. Date: Jan. 29, 2026

(54) GAS DETECTION DEVICE, GAS SUPPLY SYSTEM, AND SUBSTRATE PROCESSING APPARATUS

(71) Applicant: Tokyo Electron Limited, Tokyo (JP)

(72) Inventors: Shinobu KAWAMORITA, Oshu City (JP); Nobuo NAGATA, Oshu City (JP)

(21) Appl. No.: 19/269,456

(22) Filed: Jul. 15, 2025

(30) Foreign Application Priority Data
Jul. 23, 2024 (JP) 2024-117758

(51) Int. Cl. G01M 3/28; H01L 21/67

(52) U.S. Cl. CPC G01M 3/28; H01L 21/67017; H01L 21/67253

(57) ABSTRACT

A gas detection device for detecting a processing gas leaking into a gas box includes: a suctioner having a plurality of suction holes for sucking the processing gas at different positions in a cross section perpendicular to a central axis of an exhaust duct that evacuates an interior of the gas box; and a gas detector configured to detect the processing gas sucked by the suctioner.

### CROSS-REFERENCE TO RELATED APPLICATION

This application is based upon and claims the benefit of priority from Japanese Patent Application No. 2024-117758, filed on Jul. 23, 2024, the entire contents of which are incorporated herein by reference.

### TECHNICAL FIELD

The present disclosure relates to a gas detection device, a gas supply system, and a substrate processing apparatus.

### BACKGROUND

A technique of providing a gas sensor in an exhaust port for exhausting an atmosphere in a gas box to detect a processing gas leaking into the gas box is disclosed (see e.g., Patent Document 1).

### Prior Art Document

### Patent Document

Patent Document 1: Japanese Patent Laid-open Publication No. 2021-52110

### SUMMARY

According to an aspect of the present disclosure, a gas detection device for detecting a processing gas leaking into a gas box includes: a suctioner having a plurality of suction holes for sucking the processing gas at different positions in a cross section perpendicular to a central axis of an exhaust duct that evacuates an interior of the gas box; and a gas detector configured to detect the processing gas sucked by the suctioner.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic plan view showing a substrate processing apparatus according to an embodiment.

FIG. 2 is a schematic cross-sectional view showing the substrate processing apparatus according to the embodiment.

FIG. 3 is a view showing an example of a gas supply system according to an embodiment.

FIG. 4 is a perspective view showing a first example of a suctioner of a gas detection device.

FIG. 5 is a perspective view showing a second example of the suctioner of the gas detection device.

FIG. 6 is a perspective view showing a third example of the suctioner of the gas detection device.

FIG. 7 is a perspective view showing a fourth example of the suctioner of the gas detection device.

FIG. 8 is a view showing an evaluation system used in experiment for evaluating accuracy of detecting a processing gas.

FIG. 9 is a diagram showing results when a multi-hole nozzle is used.

FIG. 10 is a first diagram showing results when a single-hole nozzle is used.

FIG. 11 is a second diagram showing results when a single-hole nozzle is used.

FIG. 12 is a third diagram showing results when a single-hole nozzle is used.

FIG. 13 is a diagram showing an analysis result of a gas flow when suction holes are located on upper surfaces of nozzles.

FIG. 14 is a diagram showing an analysis result of a gas flow when suction holes are located on side surfaces of nozzles.

FIG. 15 is a diagram showing an analysis result of a gas flow in the absence of ducts.

FIG. 16 is a diagram showing an analysis result of a gas flow in the presence of ducts.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting exemplary embodiments of the present disclosure will be described with reference to the accompanying drawings. Throughout the accompanying drawings, the same or corresponding members or components are designated by the same or corresponding reference numerals, and duplicated descriptions thereof will be omitted.

In this specification, an X-axis, a Y-axis, and a Z-axis are orthogonal to one another. The Y-axis is an example of a first horizontal axis, the X-axis is an example of a second horizontal axis, and the Z-axis is an example of a vertical axis.

### Substrate Processing Apparatus

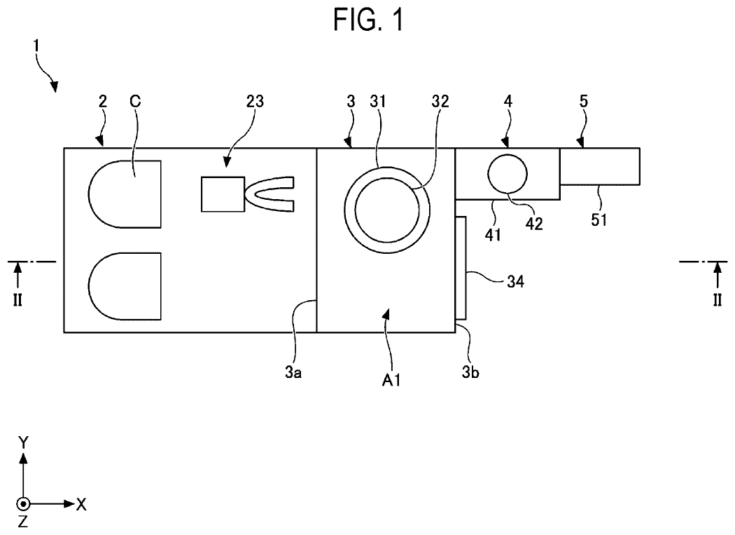

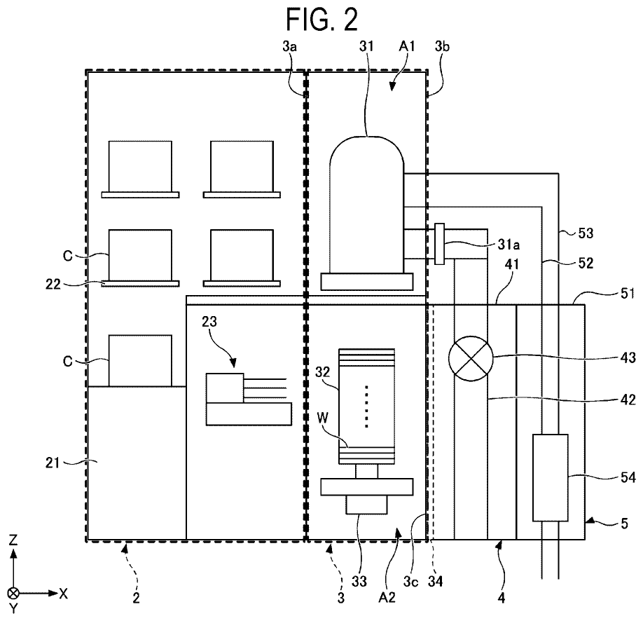

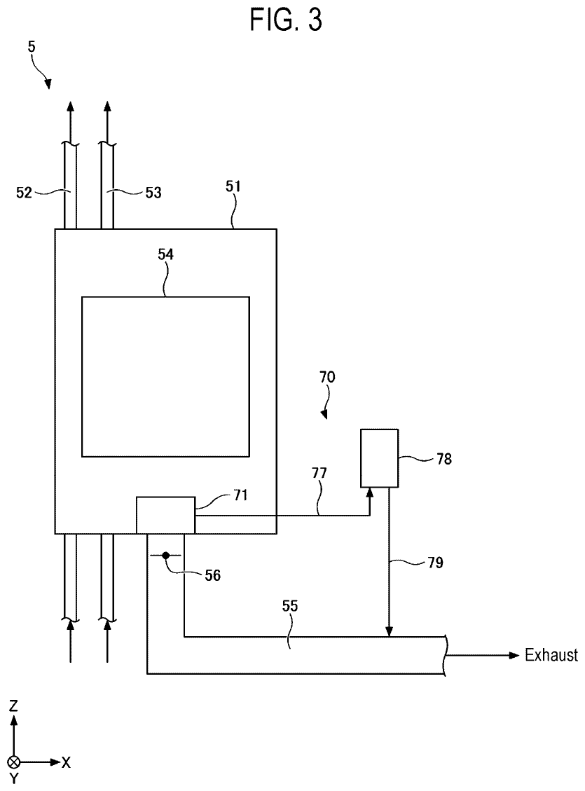

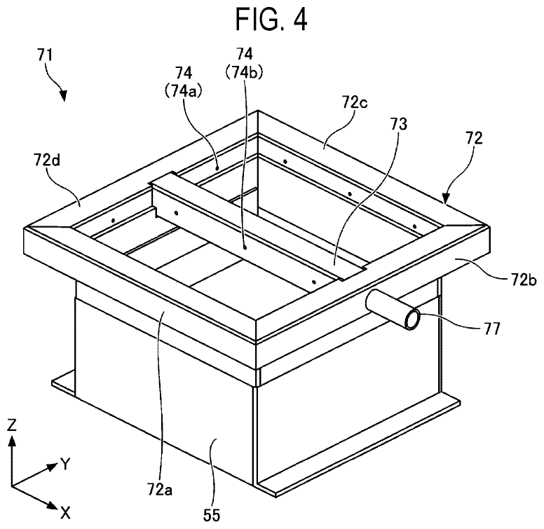

A substrate processing apparatus 1 according to an embodiment will be described with reference to FIGS. 1 to 4. FIG. 1 is a schematic plan view showing the substrate processing apparatus 1 according to an embodiment. FIG. 2 is a schematic cross-sectional view showing the substrate processing apparatus 1 according to the embodiment. FIG. 2 corresponds to a cross-sectional view taken along line II-II in FIG. 1. FIG. 3 is a view showing an example of a gas supply system 5 according to an embodiment. FIG. 4 is a perspective view showing a first example of a suctioner 71 of a gas detection device 70.

The substrate processing apparatus 1 includes a transfer module 2, a processing module 3, an exhaust unit 4, and a gas supply system 5.

The transfer module 2 is disposed adjacent to a first side wall 3a of the processing module 3. The transfer module 2 transfers a substrate W to the processing module 3. The transfer module 2 includes load ports 21, stockers 22, and a substrate transfer device 23.

The load port 21 is disposed on an X-axis negative side of the transfer module 2. A plurality of (e.g., two) load ports 21 are disposed along the Y-axis. However, the number of load ports 21 is not particularly limited. A cassette C is placed on each load port 21. The cassette C stores a plurality of (e.g., twenty-five) substrates W. The cassette C is loaded and unloaded with respect to the load port 21. The cassette C holds each substrate W horizontally. The cassette C is, for example, a front opening unified pod (FOUP).

A plurality of (e.g., two) stockers 22 are disposed on the X-axis negative side of the transfer module 2 along the Z-axis. A plurality of (e.g., two) stockers 22 are disposed on an X-axis positive side of the transfer module 2 along the Z-axis. A plurality of stockers 22 may be disposed along the Y-axis. However, the number of stockers 22 is not particularly limited. Each stocker 22 temporarily stores the cassette C.

The substrate transfer device 23 transfers the substrate W between the cassette C placed on the load port 21 and a boat 32 in the processing module 3. The substrate transfer device 23 transfers, for example, a plurality of substrates W simultaneously. For example, the substrate transfer device 23 takes out unprocessed substrates W from the cassette C placed on the load port 21 and transfers them to the boat 32. For example, the substrate transfer device 23 takes out processed substrates W from the boat 32 and transfers them to the cassette C placed on the load port 21.

The transfer module 2 may include a cassette transfer device that delivers the cassette C between the load ports 21 and the stockers 22. The transfer module 2 may include a loader for delivering the substrate to and from the substrate transfer device 23, in addition to the load port 21.

The processing module 3 includes a processing chamber A1 and a transfer chamber A2. The processing chamber A1 and the transfer chamber A2 are adjacent to each other along the Z-axis. The transfer chamber A2 is located on a Z-axis negative side of the processing chamber A1. The processing module 3 has the first side wall 3a and a second side wall 3b. The first side wall 3a is located on the X-axis negative side of the processing module 3. The second side wall 3b is located on the X-axis positive side of the processing module 3. The first side wall 3a and the second side wall 3b are spaced apart from each other in a direction along the X-axis. Each of the first side wall 3a and the second side wall 3b extends from an end of the processing module 3 on a Y-axis negative side to an end of the processing module 3 on a Y-axis positive side. Each of the first side wall 3a and the second side wall 3b extends from a lower end of the transfer chamber A2 to an upper end of the processing chamber A1.

The processing module 3 includes a processing container 31, the boat 32, a drive mechanism 33, and a maintenance door 34.

The processing container 31 is disposed in the processing chamber A1. The processing container 31 is disposed between the first side wall 3a and the second side wall 3b in the direction along the X-axis. The processing container 31 is heated by a heater (not shown). The processing container 31 is configured to accommodate the boat 32 holding the substrates W. A processing gas is supplied from the gas supply system 5 into the processing container 31. The processing gas is selected according to a type of a process. The processing gas supplied into the processing container 31 is exhausted by the exhaust unit 4. Inside the processing container 31, the substrates W held in the boat 32 are subjected to a desired process by the processing gas supplied from the gas supply system 5.

The boat 32 holds a plurality of substrates W in a shelf-like manner along the Z-axis. The boat 32 is movable between a delivery position (a position shown in FIG. 2) and a processing position. The delivery position is a position below the processing container 31. The delivery position may be directly below the processing container 31. The processing position is a position accommodated in the processing container 31, and is a position above the delivery position. The processing position may be directly above the delivery position. For example, the boat 32 moves to the delivery position when delivering the substrates W to and from the substrate transfer device 23. For example, the boat 32 moves to the processing position when performing the desired process for the substrates W.

The drive mechanism 33 is configured to move the boat 32 between the delivery position and the processing position. The drive mechanism 33 may include a boat elevator.

A maintenance opening 3c is provided in the second side wall 3b. The maintenance opening 3c is provided on the Z-axis negative side of the second side wall 3b. The maintenance opening 3c is provided at the same height as the transfer chamber A2. The maintenance opening 3c is provided, for example, at a middle position in a direction along the Y-axis. The maintenance opening 3c is an opening for performing maintenance on the processing module 3. The maintenance opening 3c is an opening for loading and unloading the processing container 31 and the boat 32 with respect to the processing module 3. Thus, the maintenance opening 3c has a size that allows the processing container 31 and the boat 32 to pass therethrough. For example, the maintenance opening 3c is used when the processing container 31 is unloaded from an interior of the processing module 3 in order to replace the processing container 31 due to damage or to clean the processing container 31. For example, the maintenance opening 3c is used when the boat 32 is unloaded from the interior of the processing module 3 in order to replace the boat 32 due to damage or to clean the boat 32.

The maintenance door 34 rotates horizontally to open and close the maintenance opening 3c.When the maintenance door 34 is open, the processing container 31 and the boat 32 can be loaded and unloaded via the maintenance opening 3c. FIG. 1 shows a state in which the maintenance door 34 is closed.

The exhaust unit 4 includes an exhaust box 41, an exhaust pipe 42, and a pressure control valve 43. The exhaust box 41 is disposed on the Y-axis positive side of the processing module 3 and is adjacent to the second side wall 3b. The exhaust pipe 42 connects an exhaust port 31a of the processing container 31 to a vacuum pump (not shown). A portion between one end and the other end of the exhaust pipe 42 is accommodated in the exhaust box 41. The pressure control valve 43 is provided inside the exhaust box 41. The pressure control valve 43 is provided in the exhaust pipe 42. The pressure control valve 43 controls an internal pressure of the processing container 31 to be a desired pressure.

The gas supply system 5 includes a gas box 51, gas supply lines 52 and 53, a fluid control device 54, an exhaust duct 55, a damper 56, and a gas detection device 70.

The gas box 51 is disposed adjacent to the X-axis positive side of the exhaust box 41. The gas box 51 has, for example, a rectangular parallelepiped shape.

The gas supply lines 52 and 53 supply the processing gas to the interior of the processing container 31. The gas supply lines 52 and 53 pass through the gas box 51. In the example of FIG. 3, two gas supply lines 52 and 53 are shown, but the number of gas supply lines is not limited to two.

The fluid control device 54 is accommodated in the gas box 51. The fluid control device 54 controls flows of the processing gas flowing through the gas supply lines 52 and 53 in the gas box 51. The fluid control device 54 includes, for example, an opening/closing valve, a mass flow controller, and a filter.

The exhaust duct 55 exhausts an atmosphere inside the gas box 51. The exhaust duct 55 is provided to penetrate a bottom plate of the gas box 51, for example.

The damper 56 is provided at an inlet of the exhaust duct 55. The damper 56 adjusts an exhaust flow rate.

The gas detection device 70 detects the processing gas leaking into the gas box 51. The gas detection device 70 includes a suctioner 71, a suction line 77, a gas detector 78, and a discharge line 79.

The suctioner 71 is provided at the inlet of the exhaust duct 55. The suctioner 71 includes an outer nozzle 72, an inner nozzle 73, and a plurality of suction holes 74.

The outer nozzle 72 is attached to a side wall of the exhaust duct 55. The outer nozzle 72 is provided along the side wall of the exhaust duct 55. The outer nozzle 72 has a rectangular annular shape. The outer nozzle 72 has an internal flow path through which the processing gas flows. The outer nozzle 72 includes a first portion 72a, a second portion 72b, a third portion 72c, and a fourth portion 72d. The first portion 72a extends along the X-axis. The second portion 72b extends along the Y-axis. The second portion 72b is connected to the first portion 72a. The third portion 72c extends along the X-axis. The third portion 72c is in parallel with the first portion 72a. The third portion 72c is connected to the second portion 72b. The fourth portion 72d extends along the Y-axis. The fourth portion 72d is in parallel with the second portion 72b. The fourth portion 72d is connected to the third portion 72c and the first portion 72a. A length of the first portion 72a and the third portion 72c along the X-axis is, for example, 150 mm. A length of the second portion 72b and the fourth portion 72d along the Y-axis is, for example, 145 mm.

The inner nozzle 73 is provided on an inner side of the outer nozzle 72. The inner nozzle 73 is provided on the same plane (XY plane) as the outer nozzle 72. The inner nozzle 73 extends, for example, along the X-axis, with one end connected to the second portion 72b and the other end connected to the fourth portion 72d. The inner nozzle 73 may extend along the Y-axis, with one end connected to the first portion 72a and the other end connected to the third portion 72c. The inner nozzle 73 is provided, for example, to pass through a center of the exhaust duct 55. The inner nozzle 73 may be provided to pass through a position offset from the center of the exhaust duct 55. The inner nozzle 73 has an internal flow path through which the processing gas flows. The internal flow path of the inner nozzle 73 is in communication with the internal flow path of the outer nozzle 72.

The suction holes 74 suck the processing gas at different positions in a cross section (XY cross section) perpendicular to a central axis of the exhaust duct 55. Each suction hole 74 has, for example, a circular shape. A hole diameter of each suction hole 74 is, for example, 0.8 mm or more and 1.2 mm or less. In this case, variation in an amount of suction from each suction hole 74 can be reduced. The number of the suction holes 74 is, for example, sixteen. In this case, an internal pressure of the outer nozzle 72 and an internal pressure of the inner nozzle 73 are reduced, and the processing gas is easily sucked into the outer nozzle 72 and the inner nozzle 73. The suction holes 74 include outer suction holes 74a and inner suction holes 74b.

The outer suction holes 74a are provided in the outer nozzle 72. In a cross section perpendicular to the central axis of the exhaust duct 55, the outer suction holes 74a are provided closer to the side wall than the center of the exhaust duct 55. In the example of FIG. 4, ten outer suction holes 74a are provided. A central axis of each of the outer suction holes 74a is inclined with respect to the central axis of the exhaust duct 55. In this case, a pressure difference between an interior of the outer nozzle 72 and a periphery of the outer nozzle 72 becomes small, and an outflow of the processing gas from the interior of the outer nozzle 72 can be suppressed. An inclination angle of the central axis of each of the outer suction holes 74a with respect to the central axis of the exhaust duct 55 is, for example, 45 degrees or more and 90 degrees or less, and is 90 degrees in the example of FIG. 4. The outer suction holes 74a are provided on an inner surface of the outer nozzle 72 and are open toward the center of the exhaust duct 55.

The inner suction holes 74b are provided in the inner nozzle 73. In a cross section perpendicular to the central axis of the exhaust duct 55, the inner nozzle 73 is provided closer to the center of the exhaust duct 55 than the outer suction holes 74a. In the example of FIG. 4, six inner suction holes 74b are provided. A central axis of each of the inner suction holes 74b is inclined with respect to the central axis of the exhaust duct 55. In this case, a pressure difference between an interior of the inner nozzle 73 and a periphery of the inner nozzle 73 becomes small, and an outflow of the processing gas from the interior of the inner nozzle 73 can be suppressed. An inclination angle of the central axis of each of the inner suction holes 74b with respect to the central axis of the exhaust duct 55 is, for example, 45 degrees or more and 90 degrees or less, and is 90 degrees in the example of FIG. 4. In the example of FIG. 4, three inner suction holes 74b are provided on a surface facing the first portion 72a among side surfaces of the inner nozzle 73, and three inner suction holes 74b are provided on a surface facing the third portion 72c among the side surfaces of the inner nozzle 73.

The suction line 77 is connected to the suctioner 71. In the example of FIG. 4, the suction line 77 is provided to penetrate an outer surface of the second portion 72b. The suction line 77 allows the processing gas sucked by the suctioner 71 to flow into the gas detector 78.

The gas detector 78 detects the processing gas flowing in from the suction line 77. The processing gas flowing out from the gas detector 78 flows through the exhaust duct 55 via the discharge line 79.

The discharge line 79 has one end connected to the gas detector 78, and the other end connected to the exhaust duct 55 on a downstream side of the damper 56 in the flow of the processing gas. The discharge line 79 allows the processing gas flowing out from the gas detector 78 to flow through the exhaust duct 55.

As described above, according to the embodiment, the gas detection device 70 includes the suctioner 71, the suction line 77, and the gas detector 78. The suctioner 71 has the suction holes 74. The suction holes 74 suck the processing gas at different positions in a cross section perpendicular to the central axis of exhaust duct 55. The suction line 77 is connected to the suctioner 71. The gas detector 78 detects the processing gas flowing in from the suction line 77. In this case, the processing gas can be sucked in from an entirety of the cross section perpendicular to the central axis of exhaust duct 55. Thus, it is possible to improve accuracy of detecting the processing gas leaking into the gas box 51.

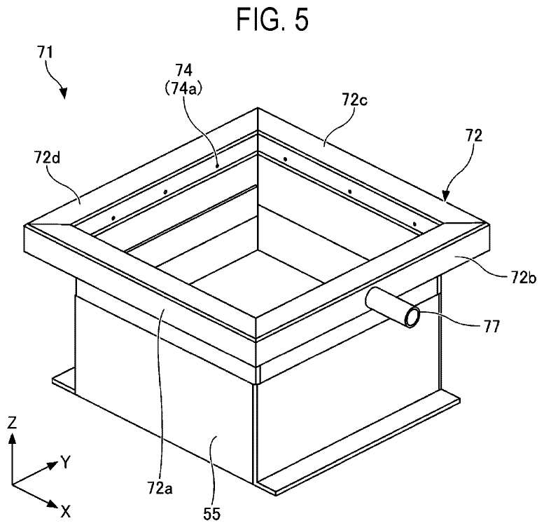

FIG. 5 is a perspective view showing a second example of the suctioner 71 of the gas detection device 70. As shown in FIG. 5, the suctioner 71 may not include the inner nozzle 73. In this case, a conductance of the exhaust duct 55 increases.

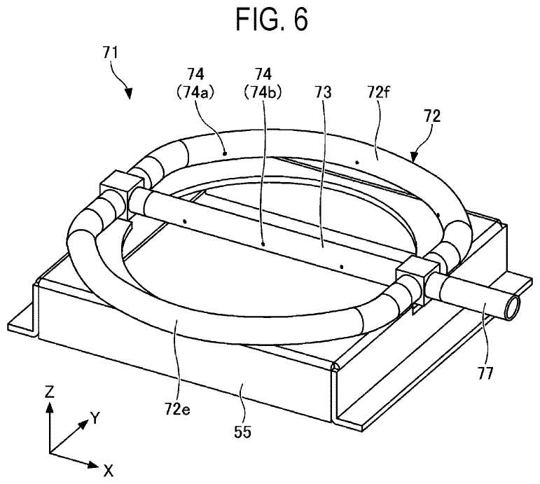

FIG. 6 is a perspective view showing a third example of the suctioner 71 of the gas detection device 70. As shown in FIG. 6, when a flow path of the processing gas at the inlet of exhaust duct 55 is circular in a plan view, the outer nozzle 72 may have a substantially circular annular shape in a plan view. The outer nozzle 72 may be formed by connecting a semicircular ring-shaped fifth portion 72e and a semicircular ring-shaped sixth portion 72f.

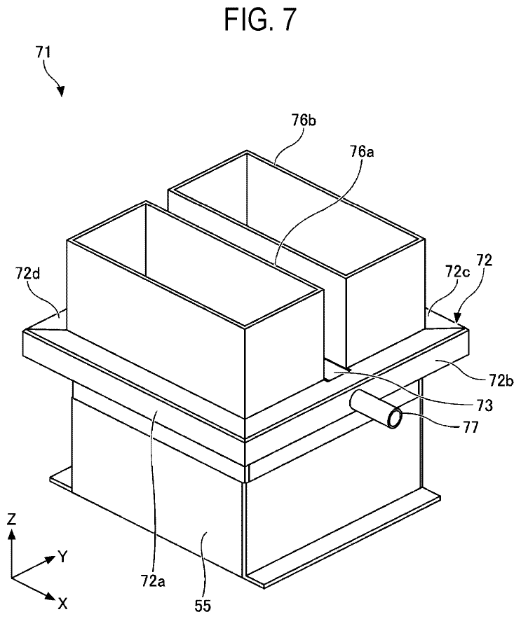

FIG. 7 is a perspective view showing a fourth example of the suctioner 71 of the gas detection device 70. As shown in FIG. 7, the suctioner 71 may further include ducts 76a and 76b. The ducts 76a and 76b have a rectangular cylindrical shape. The ducts 76a and 76b rectify the processing gas into a flow along the Z-axis on an upstream side of the suction holes 74 in the flow of the processing gas. In this case, the processing gas is easily sucked into the outer nozzle 72 and the inner nozzle 73. A length of the ducts 76a and 76b along the Z-axis is, for example, 50 mm or more. In this case, the processing gas is easily rectified into the flow along the Z-axis. The duct 76a rectifies a flow of the processing gas, which flows into a region surrounded by the first portion 72a, the second portion 72b, the fourth portion 72d, and the inner nozzle 73, into a flow along the central axis of exhaust duct 55. The duct 76b rectifies a flow of the processing gas, which flows into a region surrounded by the second portion 72b, the third portion 72c, the fourth portion 72d, and the inner nozzle 73, into a flow along the central axis of the exhaust duct 55. The ducts 76a and 76b are examples of a flow rectifier.

### Experimental Results

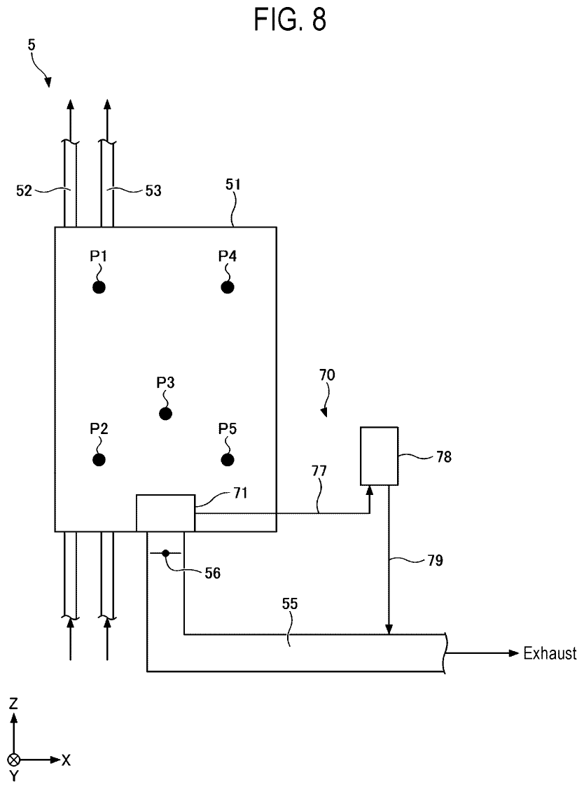

Results of experiments for evaluating accuracy of detecting the processing gas will be described with reference to FIGS. 8 to 12. FIG. 8 shows an evaluation system used in experiments for evaluating accuracy of detecting the processing gas. In FIG. 8, illustration of the fluid control device 54 is omitted.

In the experiments, hydrogen gas diluted with nitrogen gas (hereinafter also referred to as “diluted hydrogen gas”) was discharged (leaked) in different directions from different positions in the gas box 51, and whether or not the gas detector 78 detects the hydrogen gas was measured. In the experiments, the outer nozzle 72 (hereinafter also referred to as “multi-hole nozzle”) having the plurality of outer suction holes 74a shown in FIG. 5 was used. In the experiments, the diluted hydrogen gas was discharged in one of six directions from one of five positions P1 to P5. The position P1 is a position (upper left position) on the X-axis negative side and the Z-axis positive side. The position P2 is a position (lower left position) on the X-axis negative side and the Z-axis negative side. The position P3 is a position (center position) at a center of the X-axis and a center of the Z-axis. The position P4 is a position (upper right position) on the X-axis positive side and the Z-axis positive side. The position P5 is a position (lower right position) on the X-axis positive side and the Z-axis negative side. The six directions include a Z-axis positive direction (upward), a Z-axis negative direction (downward), an X-axis negative direction (leftward), an X-axis positive direction (rightward), a Y-axis negative direction (frontward), and a Y-axis positive direction (rearward).

For comparison, nozzles (hereinafter also referred to as “single-hole nozzles”) having a single suction hole were used instead of the outer nozzle 72. Specifically, a nozzle having a suction hole only on the X-axis negative side and having a detection position on the X-axis negative side (left side), a nozzle having a suction hole only at the center of the X-axis and having a detection position at the center of the X-axis (center side), and a nozzle having a suction hole only on the X-axis positive side and having a detection position on the X-axis positive side (right side) were used.

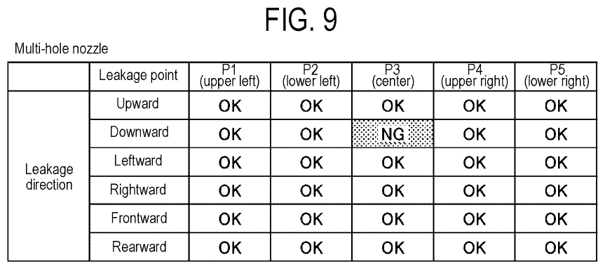

FIG. 9 is a diagram showing results when the multi-hole nozzle was used. In FIG. 9, “OK” means that the gas detector 78 detected the hydrogen gas, and “NG” means that the gas detector 78 did not detect the hydrogen gas. As shown in FIG. 9, when the multi-hole nozzle was used, the gas detector 78 detected the hydrogen gas except for one condition (where a leakage point is the position P3 and a leakage direction is downward).

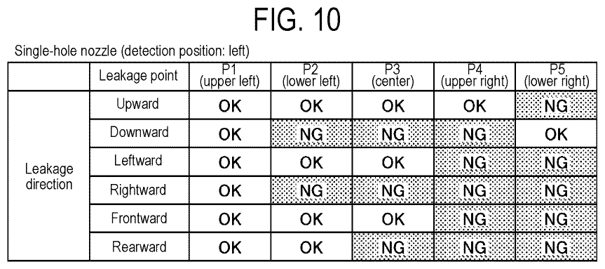

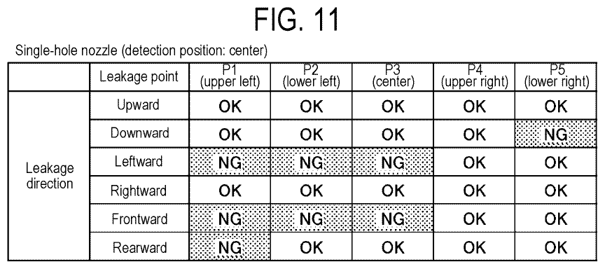

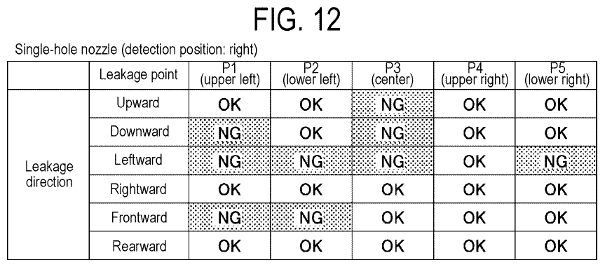

FIGS. 10 to 12 are diagrams showing results when the single-hole nozzles were used. In FIGS. 10 to 12, “OK” means that the gas detector 78 detected the hydrogen gas, and “NG” means that the gas detector 78 did not detect the hydrogen gas. FIG. 10 shows results when the detection position is on the left side, FIG. 11 shows results when the detection position is on the center side, and FIG. 12 shows results when the detection position is on the right side. As shown in FIG. 10, when the single-hole nozzle having a detection position on the left side was used, the gas detector 78 did not detect the hydrogen gas under fifteen conditions. As shown in FIG. 11, when the single-hole nozzle having a detection position on the center side was used, the gas detector 78 did not detect the hydrogen gas under eight conditions. As shown in FIG. 12, when the single-hole nozzle having a detection position on the right side was used, the gas detector 78 did not detect the hydrogen gas under nine conditions.

The results of FIGS. 9 to 12 show that by using the multi-hole nozzle, it is possible to improve accuracy of detecting the processing gas leaking into the gas box 51.

In addition, as shown in FIG. 11, when the single-hole nozzle having the detection position on the center side was used, the hydrogen gas was detected under the condition that the leakage point is the position P3 and the leakage direction is downward. From this result, it is considered that by adding the inner nozzle 73 having the plurality of inner suction holes 74b to the outer nozzle 72 having the plurality of outer suction holes 74a as shown in FIG. 5, the hydrogen gas can be detected under the condition that the leakage point is the position P3 and the leakage direction is downward. In other words, it is considered that the hydrogen gas can be detected under all conditions by using the suctioner 71 shown in FIG. 4.

### Simulation Results

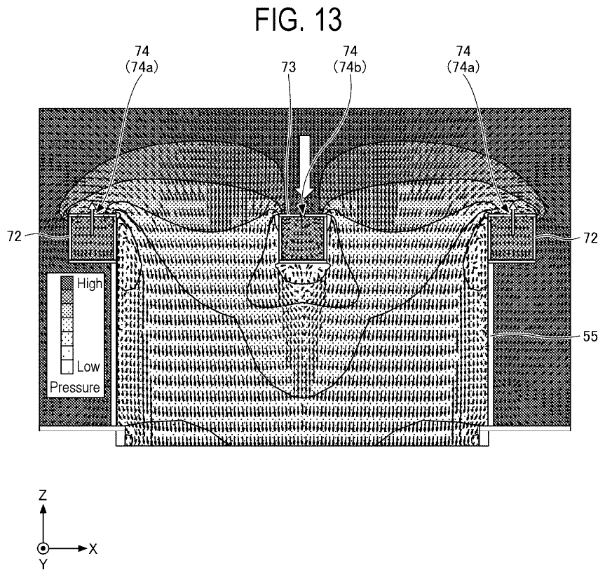

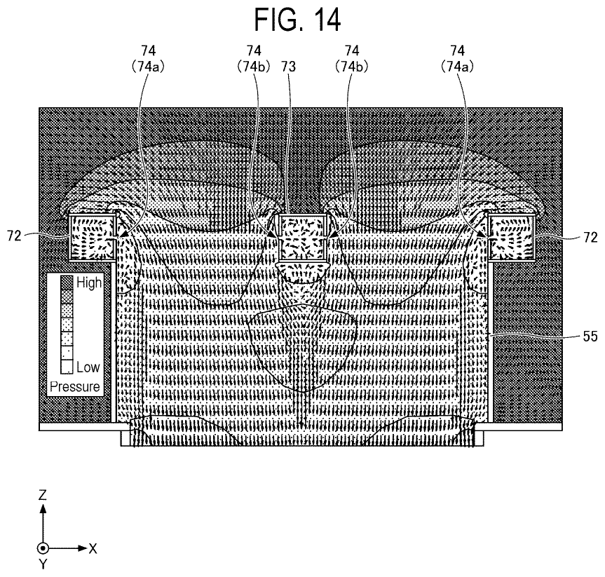

Results of analyzing gas flows when the suction holes 74 have different orientations will be described with reference to FIGS. 13 and 14. FIG. 13 is a diagram showing an analysis result of a gas flow when the suction holes 74 are located on upper surfaces of nozzles. Specifically, in FIG. 13, the outer suction holes 74a are located on the upper surface of the outer nozzle 72, and the inner suction holes 74b are located on the upper surface of the inner nozzle 73. FIG. 14 is a diagram showing an analysis result of a gas flow when the suction holes 74 are located on side surfaces of nozzles. Specifically, in FIG. 14, the outer suction holes 74a are located on the side surface of the outer nozzle 72, and the inner suction holes 74b are located on the side surface of the inner nozzle 73. FIGS. 13 and 14 show the analysis results of the gas flows in a YZ cross section passing through the center of the exhaust duct 55.

As shown in FIG. 13, when the inner suction holes 74b are located on the upper surface of the inner nozzle 73, a gas in the gas box 51 flows from the inner suction holes 74b into the inner nozzle 73 without colliding with the inner nozzle 73. In this case, the internal pressures of the inner nozzle 73 and the outer nozzle 72 increase. Thus, a gas in the outer nozzle 72 easily flows from the outer suction holes 74a to an outside of the outer nozzle 72.

As shown in FIG. 14, when the outer suction holes 74a are located on the side surface of the outer nozzle 72 and the inner suction holes 74b are located on the side surface of the inner nozzle 73, the pressure difference between the interior of the outer nozzle 72 and the periphery of the outer nozzle 72 and the pressure difference between the interior of the inner nozzle 73 and the periphery of the inner nozzle 73 become small. In this case, substantially no gas flows out from the outer nozzle 72 and the inner nozzle 73. Therefore, a gas flowing into the outer nozzle 72 and the inner nozzle 73 easily flows into the gas detector 78 via the suction line 77. As a result, accuracy of detecting the gas by the gas detector 78 is improved.

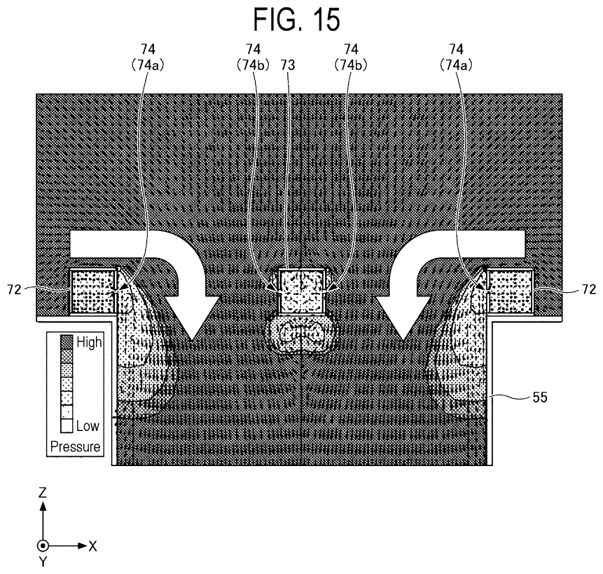

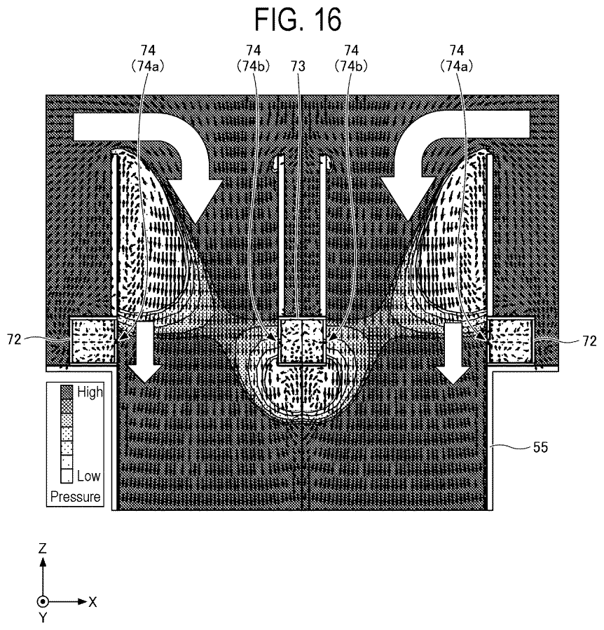

Results of analyzing gas flows in the presence of the ducts 76a and 76b and in the absence of the ducts 76a and 76b will be described with reference to FIGS. 15 and 16. FIG. 15 is a diagram showing an analysis result of a gas flow in the absence of the ducts 76a and 76b. FIG. 16 is a diagram showing an analysis result of a gas flow in the presence of the ducts 76a and 76b. FIGS. 15 and 16 show the analysis results of gas flows in the YZ cross section passing through the center of the exhaust duct 55.

As shown in FIG. 15, in the absence of the ducts 76a and 76b, a gas flow around the outer nozzle 72 changes sharply from the horizontal direction to the vertical direction. In this case, a pressure around the outer nozzle 72 is reduced, and a vortex is generated. Thus, a gas hardly flows into the outer nozzle 72.

As shown in FIG. 16, in the presence of the ducts 76a and 76b, a gas flow around the outer nozzle 72 is made vertical by the ducts 76a and 76b. In this case, a gas easily flows into the outer nozzle 72. Thus, since an amount of the gas flowing into the gas detector 78 via the suction line 77 increases, accuracy of detecting the gas by the gas detector 78 is improved.

According to the present disclosure in some embodiments, it is possible to improve accuracy of detecting a processing gas leaking into a gas box.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A gas detection device for detecting a processing gas leaking into a gas box, comprising:
a suctioner having a plurality of suction holes for sucking the processing gas at different positions in a cross section perpendicular to a central axis of an exhaust duct that evacuates an interior of the gas box; and
a gas detector configured to detect the processing gas sucked by the suctioner.

2. The gas detection device of claim 1, wherein the plurality of suction holes includes two or more outer suction holes, which are provided closer to a side wall of the exhaust duct than to a center of the exhaust duct in the cross section.

3. The gas detection device of claim 2, wherein the plurality of suction holes includes one or more inner suction holes, which are provided closer to the center of the exhaust duct than the outer suction holes in the cross section.

4. The gas detection device of claim 3, wherein the suctioner is provided at an inlet of the exhaust duct.

5. The gas detection device of claim 1, wherein a central axis of each of the plurality of suction holes is inclined with respect to the central axis of the exhaust duct.

6. The gas detection device of claim 5, wherein an inclination angle of the central axis of each of the plurality of suction holes with respect to the central axis of the exhaust duct is 45 degrees or more and 90 degrees or less.

7. The gas detection device of claim 1, wherein the suctioner is provided at an inlet of the exhaust duct.

8. The gas detection device of claim 1, further comprising:
a flow rectifier configured to rectify, on an upstream side of the plurality of suction holes in a flow of the processing gas, the processing gas into a flow along the central axis of the exhaust duct.

9. A gas supply system comprising:
a gas supply line configured to supply a processing gas into a processing container;
a fluid control device provided in the gas supply line;
a gas box configured to accommodate the fluid control device;
an exhaust duct configured to evacuate an interior of the gas box; and
a gas detection device configured to detect the processing gas leaking into the gas box,
wherein the gas detection device includes:
a suctioner having a plurality of suction holes for sucking the processing gas at different positions in a cross section perpendicular to a central axis of the exhaust duct; and
a gas detector configured to detect the processing gas sucked by the suctioner.

10. A substrate processing apparatus comprising:
a processing container configured to accommodate a substrate;
a gas supply line configured to supply a processing gas into the processing container;
a fluid control device provided in the gas supply line;
a gas box configured to accommodate the fluid control device;
an exhaust duct configured to evacuate an interior of the gas box; and
a gas detection device configured to detect the processing gas leaking into the gas box,
wherein the gas detection device includes:
a suctioner having a plurality of suction holes for sucking the processing gas at different positions in a cross section perpendicular to a central axis of the exhaust duct; and
a gas detector configured to detect the processing gas sucked by the suctioner.
